(19) United States
(12) Patent Application Publication
(10) Pub. No.: US 2013/0032929 A1
(43) Pub. Date: Feb. 7, 2013

(54) METHOD OF PROTECTING DEEP TRENCH SIDEWALL FROM PROCESS DAMAGE

(71) Applicant: Effendi Leobandung, Hopewell Junction, NY (US)

(72) Inventor: Effendi Leobandung, Hopewell Junction, NY (US)

(73) Assignee: INTERNATIONAL BUSINESS MACHINES CORPORATION, Armonk, NY (US)

(21) Appl. No.: 13/198,873

(22) Filed: Aug. 5, 2011

(51) Int. Cl. H01L 23/482; H01L 21/311

(52) U.S. Cl. 257/621; 438/699; 257/E21.257; 257/E23.017

(57) ABSTRACT

Method of protecting a liner in a previously formed deep trench module from subsequent processing steps, and resulting structure. A deep trench module includes a deep trench with one or more liner films and a fill material in an SOI substrate. A mask layer is patterned to form first and second masks aligned over the liner films on first and second sidewalls of the deep trench, respectively. Further etching creates a polysilicon tab under the first mask which protects the liner film adjacent the first sidewall from being exposed during subsequent etches. The second mask protects its underlying polysilicon from subsequent etches to maintain a conduction strap from SOI layer to deep trench. The masks are removed. An isolation film is deposited on the substrate and planarized to form and isolation region. The resulting structure has a polysilicon tab interposed between the deep trench liner and the isolation region.

### BACKGROUND OF THE INVENTION

1. Field of the Invention

The present invention generally relates to semiconductors and a method of making embedded dynamic random access memory (eDRAM) chips having deep trenches in a silicon on insulator (SOI) substrate. In particular, the invention relates to an improved integration scheme which protects film(s) lining the sidewall of the deep trench during subsequent processing steps. The resulting structure is also described.

2. Description of Related Art

U.S. Pat. No. 6,281,069 to Wu et al. (herein “Wu”) discloses DRAM manufacturing using deep trench capacitors in bulk silicon substrates. The capacitor includes a buried plate of a doped substrate, a node dielectric and a second plate which is a polysilicon material filling at least a portion of the trench. The deep trench itself has three sections with three polycrystalline silicon regions (herein “polysilicon” or “polySi” or “poly”). The bottom region, Poly1, forms the capacitor; the middle region, Poly2, is surrounded by an isolation collar; and the top region, Poly3, connects to an active area via a strap. Subsequent to deep trench capacitor formation, a shallow trench isolation (herein “STI”) is made over the trench. The depth of the STI exposes at least a part of the collar. In Wu, the STI and collar serve an isolation function between two adjacent trench capacitors.

Deep trenches can also be manufactured in a SOI substrate. In SOI substrates, a trench capacitor can have a titanium nitride (herein “TiN”) first plate, a hafnium oxide node dielectric, and polysilicon second plate. The first plate and node dielectric line the trench and the second plate is polysilicon (Poly1) which fills a portion of the trench. The second plate, may also include a TiN liner interposed between the node dielectric and the Poly1. With an SOI substrate, a buried oxide (herein “Box”) region of the SOI substrate replaces the collar isolation of a bulk substrate deep trench. The Box area of the trench is filled with an intrinsic polysilicon layer (Poly2). The Poly2 region can also serve as a strap to the SOI layer (i.e. the layer of silicon on top of the Box). Furthermore, an STI opening is etched in the Poly2 region and filled to isolate the trench capacitor. The depth of the STI opening reaches the Box region. However, the etching to form the STI opening can expose the previously formed deep trench fill and lining materials. The exposed liner and fill materials are vulnerable to damage by the STI etch itself and subsequent cleaning steps which cause unintended etching of the liner. Alternatively, if a mild clean is used to avoid etching, residue can be left. Either way, there is a yield impact to SOI deep trench devices.

### SUMMARY

Therefore, there is a need for an integration scheme which protects films lining the deep trench from being exposed during subsequent process steps.

In one embodiment, a method protects a liner film adjacent a deep trench sidewall from exposure during subsequent processing steps by forming a first mask vertically aligned over the liner film which in turn creates a tab vertically aligned over the sidewall liner. The starting point of the method is providing a semiconductor on insulator (herein “SOI”) substrate having an SOI layer above an insulator layer (also referred to as the “buried oxide” or “Box”), and a deep trench. The deep trench is filled with a silicon containing material. The deep trench has a lower portion and an upper portion. In the lower portion, a first sidewall of the deep trench has an adjacent liner film. A mask layer is deposited above the substrate and patterned to form a first mask which is aligned over the liner film on the first sidewall of the deep trench. A first silicon etch partially etches the silicon containing material and the SOI layer to form a tab under the first mask which is also aligned above the liner film. In a further embodiment, the first mask is removed and a second silicon etch is performed. The second silicon etch etches more of the silicon containing material to form a strap adjacent the Box layer, etches the tab thus shortening it, and completely etches the SOI layer to expose the underlying insulator (Box) layer. In yet another embodiment, an isolation film is deposited over the substrate and planarized to form an isolation region over the tab.

In another embodiment of the invention, by using a single lithography step, two self-aligned masks are formed. The first mask protects a deep trench liner from damage during processing and the second mask forms a strap. The method includes providing a substrate with a deep trench and a pad layer. The pad layer has an opening which is aligned over the deep trench. A mask layer is conformally deposited to cover the pad layer and follow the opening to cover the deep trench. The deep trench has a first sidewall and a second sidewall; both sidewalls have a liner on their lower portions. A silicon containing material covers fills the deep trench. A lithography stack is deposited, exposed and etched so that it has an opening over first sidewall. The mask layer exposed by the opening in the lithographic stack is etched (like a spacer etch) to form a first mask (after the pad layer is removed). With the first mask in place, a portion of the silicon containing material is etched to form a tab which is self-aligned over the first sidewall (and its liner film). The lithographic stack is removed and another spacer-like etch of the now unmasked mask layer creates a second mask aligned over the second sidewall of the deep trench. A second silicon etch removes silicon containing material to form a strap of silicon containing material aligned over the second sidewall.

Another embodiment of the invention provides an embedded DRAM (herein “eDRAM”). The eDRAM is built on a semiconductor on insulator (SOI) substrate having an SOI layer, insulator layer (also referred to as “buried oxide” or “box”) and bulk layer. The eDRAM has a deep trench in the substrate. The deep trench has a first sidewall, a liner adjacent the first sidewall and a silicon containing fill material. The eDRAM also has a strap portion of the silicon containing fill material adjacent the SOI layer, and a tab portion of the silicon containing fill material aligned over the liner adjacent the first sidewall. There is an isolation film above the tab and on either side of the tab.

In one embodiment of the invention, a substrate is provided. The substrate has a deep trench with a liner on a lower portion of a first sidewall of the deep trench, and the deep trench is filled with a polysilicon. An isolation region intersects a top portion of the first sidewall and a portion of the polysilicon fill material such that the polysilicon fill material is interposed between the liner and the isolation region.

### BRIEF DESCRIPTION OF THE DRAWINGS

FIG. 1 illustrates a flow chart of the steps to protect a liner in a deep trench from exposure during subsequent processing steps according to an embodiment of the present invention;

FIG. 2 illustrates a starting point of the method which provides a SOI substrate having a deep trench and pad layer with an opening to the deep trench according to an embodiment of the present invention;

FIG. 3 illustrates a SOI substrate after formation of a mask layer over the pad layer and over the opening to the top of the deep trench. On top of mask layer is a lithographic film stack with an opening in the resist layer formed according to an embodiment of the present invention;

FIG. 4 illustrates a SOI substrate with deep trench, pad layer, mask layer, and lithographic film stack after the lithographic film stack has been etched according to an embodiment of the present invention;

FIG. 5 illustrates a SOI substrate after patterning the mask layer to form a first mask spacer according to an embodiment of the present invention;

FIG. 6 illustrates a SOI substrate after selective etching of the pad layer to form a first mask according to an embodiment of the present invention;

FIG. 7 illustrates a SOI substrate after a first silicon etch to form a tab under the first mask according to an embodiment of the present invention.

FIG. 8 illustrates a SOI substrate after removal of the first mask and formation of the second mask according to an embodiment of the present invention.

FIG. 9 illustrates a SOI substrate after a second silicon etch according to an embodiment of the present invention.

FIG. 10 illustrates a SOI substrate after isolation film deposition and planarization according to an embodiment of the present invention.

FIG. 11 illustrates a SOI substrate after pad layer removal and isolation region formation according to an embodiment of the present invention.

Other objects, aspects and advantages of the invention will become obvious in combination with the description of accompanying drawings, wherein the same number represents the same or similar parts in all figures.

### DETAILED DESCRIPTION OF EMBODIMENTS

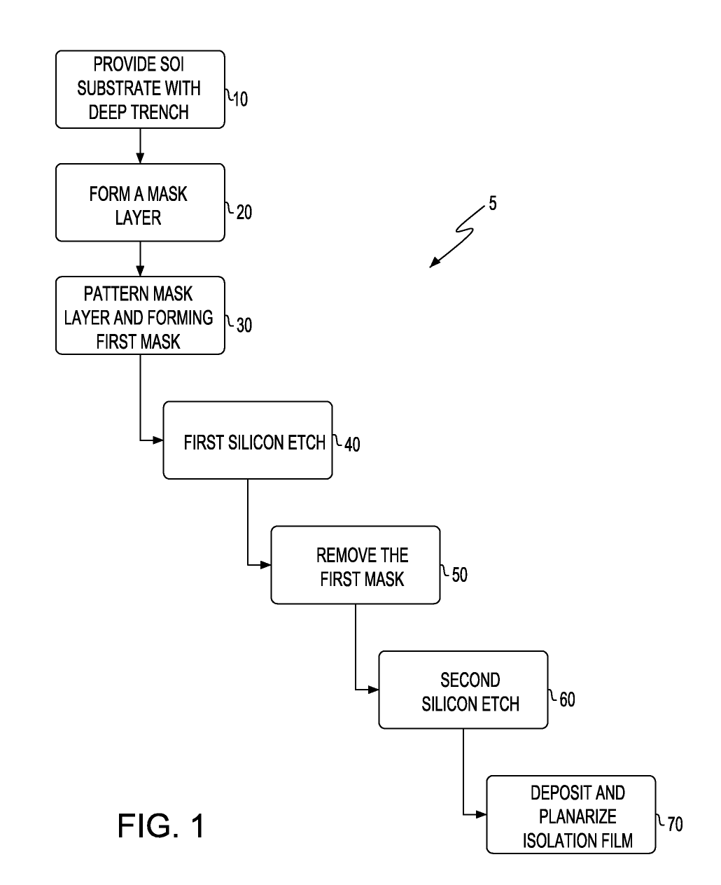

In an embodiment of the invention, a method of protecting a previously formed liner in a deep trench from subsequent processing steps is described in conjunction with FIGS. 1-11.

FIG. 1 is a simplified flow chart 5 illustrating steps to protect a previously formed liner of a deep trench from exposure during subsequent processing steps according to one embodiment. Step 10 is providing a SOI substrate having a deep trench with liner and fill materials previously formed; step 20 is forming a blanket mask layer on the SOI substrate; step 30 is patterning the mask layer and forming a first mask over a portion of the deep; step 40 is a first silicon etch step to partially etch the SOI layer; step 50 is removing the first mask; step 60 is a second silicon etching step, thus completing the etch of the SOI layer; step 70 is depositing an isolation film in an opening created by the first and second silicon etches and then planarizing the isolation film to be co-planar with the SOI layer. Each of the steps will be discussed in detail below. Those skilled in the art will recognize that the step number (10, 20, 30, etc.) does not necessarily indicate an order to perform the step; rather the step numbers are reference numerals used as a means of step identification.

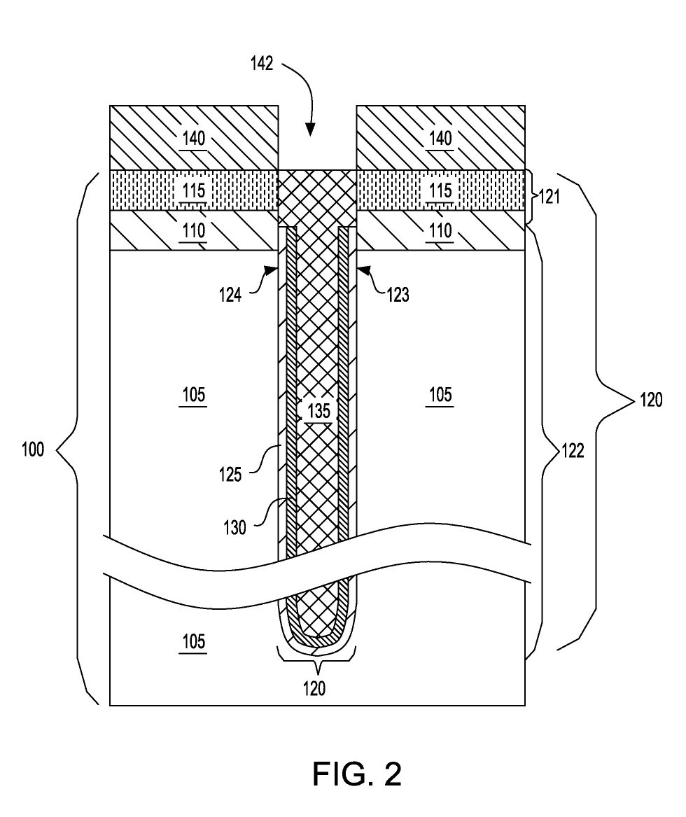

Referring to FIG. 2, a starting point for one of the embodiment of the invention is shown. First, substrate 100 is preferably a semiconductor on insulator substrate (SOI substrate 100). An SOI substrate has three parts: a bottom bulk semiconductor 105 portion, a middle insulator layer 110 (herein “box” which stands for “buried oxide”), and a top semiconductor on insulator 115 layer (herein “SOI layer”). Preferably, the bulk 105 portion is silicon or some variant of doped silicon. Preferably, the Box 110 is an oxide and more preferably silicon dioxide. The SOI layer 115, can be silicon, silicon doped with conventional n-dopants or p-dopants, silicon germanium (SiGe), silicon germanium carbon (SiGeC), silicon carbon (SiC), III-V semiconductor compounds (for example In₁₋ₓGaₓAs, InP, GaAs) or other variations. The thickness of the SOI layer 115 can vary and is preferably from about 30 nm to 60 nm and ranges therebetween.

Referring still to FIG. 2, a deep trench 120 has been etched into the substrate 100. The deep trench 120 can have a depth from about 1 um to about 7 um and ranges therebetween. The deep trench has an upper portion 121 and a lower portion 122. The lower portion 122 of the deep trench 120 is lined with a liner film. In a preferred embodiment, the liner film is a composite of two layers including a node dielectric 125 and a metal layer 130. However, the liner film may be a single layer of either of the previously mentioned layers or may be another layer. Furthermore, in other embodiments, the liner film can be made of more than two layers. The deep trench is filled with a fill material 135. At the upper portion 121 of the deep trench 120, because there is no liner (node layer 125 or metal layer 130 of FIG. 2), the fill material 135 is in direct contact with the sidewalls (first sidewall 123, and second sidewall 124) of the deep trench 120.

The positioning of the upper 121 and lower 122 portions of the deep trench 120 relative to SOI substrate 100 should be noted. The upper portion 121 is adjacent the SOI layer 115 and can extend downward to be adjacent a portion of the Box layer 110. The lower portion 122 of the deep trench 120 is adjacent the bulk 105 part of the substrate and can extend upward to be adjacent the entire Box 110 height or adjacent a portion of the Box 110 height (as shown in the Figures).

The node dielectric 125 is preferably a high dielectric constant material (herein “high-k”). Suitable high-k materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k may further include dopants such as lanthanum, aluminum. High-k material can be deposited by any suitable process, including but not limited to, atomic layer deposition (ALD), molecular layer deposition (MLD), chemical vapor deposition (CVD), plasma enhanced chemical vapor deposition (PECVD), high density plasma chemical vapor deposition (HDPCVD), rapid thermal chemical vapor deposition (RTCVD), in-situ radical assisted deposition, ultrahigh vacuum chemical vapor deposition (UHVCVD), metal organic chemical vapor deposition (MOCVD), molecular beam epitaxy (MBE), physical vapor deposition, sputtering, evaporation, ion beam deposition, electron beam deposition, laser assisted deposition, chemical solution deposition, or any combination of those methods. The high-k thickness may range from 2 nm to 6 nm or any other range in between. An interfacial layer such as silicon oxide, silicon nitride, silicon oxynitride (not shown) may be formed on the sidewalls 123, 124 of the deep trench 120 before high-k deposition. In a preferred embodiment the node dielectric is hafnium oxide (HfO₂) deposited by ALD.

The metal layer 130 lining the deep trench 120 is preferably TiN. Alternatively, the metal layer 130 can be germanium, silicon germanium, a metal (e.g., tungsten, titanium, tantalum, ruthenium, zirconium, cobalt, copper, aluminum, lead, platinum, tin, silver, gold), a conducting metallic compound material (e.g., tantalum nitride, titanium nitride, tungsten silicide, tungsten nitride, ruthenium oxide, cobalt silicide, nickel silicide), carbon nanotube, conductive carbon, or any suitable combination of these materials. Suitable processes described above for high-k deposition can be used for forming metal layer 130. The thickness of the metal layer 130 can range from 1 nm to 10 nm and ranges therebetween.

The fill material 135 of the deep trench 120 is, in a preferred embodiment, doped polycrystalline silicon. Dopants include common n-dopants or p-dopants used in semiconductor fabrication. The fill material 135 may also be undoped poly, also known as intrinsic poly. In FIG. 2, the fill material 135 is depicted as the same material in the lower portion 122 of the deep trench as in the upper portion 121 of the deep trench. However, the fill material 135 may be a composite such that the lower portion 122 of the deep trench is comprised of a first type of fill material and the upper portion 121 of the deep trench 120 is comprised of a second type of fill material. For example, the first type of fill material can be doped poly whereas the second type of fill material can be intrinsic poly. In a preferred embodiment, the fill material is a doped polycrystalline silicon at both the upper 121 and lower 122 portion of the deep trench 120.

Referring still to FIG. 2, pad layer 140 is above the SOI layer 115. The pad layer includes a nitrogen containing film. The pad layer 140, in a preferred embodiment, is actually a film stack including, a top film of a nitride containing material and a bottom film of an oxygen containing material. In a preferred embodiment, the top film is silicon nitride and the bottom film is silicon dioxide. In a preferred embodiment, the nitride containing film is from about 20 nm to about 100 nm and ranges therebetween while the oxygen containing film is from about 1 nm to about 5 nm and ranges therebetween. FIG. 2 shows an opening 142 in the pad layer which exposes the fill material 135 at the top of the deep trench 120.

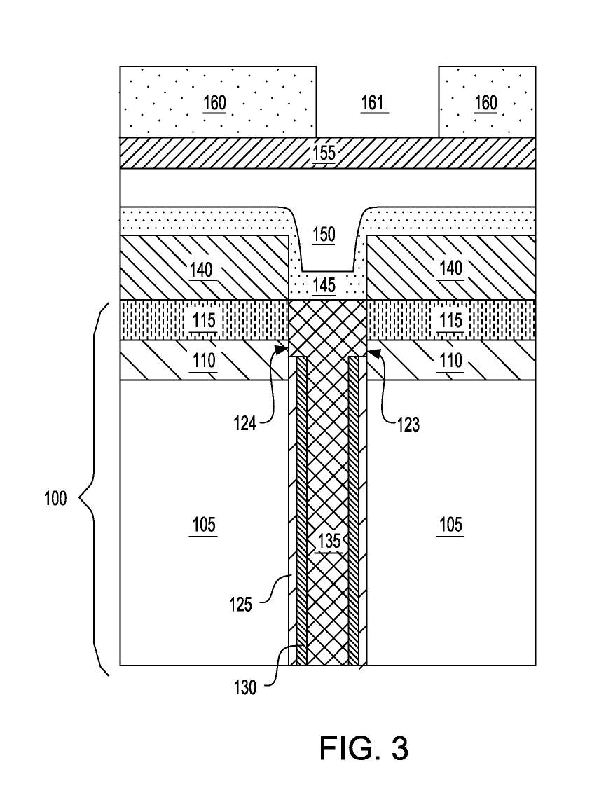

Referring to FIG. 3, the substrate is shown after mask layer 145 formation and lithographic films (150, 155, and 160) deposition. The mask layer 145 can be any oxygen containing film, but is preferably silicon dioxide. The mask layer 145 can be deposited by a variety of techniques including, but not limited, to chemical vapor deposition, plasma enhanced chemical vapor deposition, and atomic layer deposition. In a preferred embodiment, a silicon dioxide film is formed by low temperature oxidation so as to form a mask layer 145 over the pad layer 140, into the opening 142 of the pad layer and over the top of the deep trench 120. The thickness of the mask layer 145 can be from about 5 nm to about 30 nm and ranges therebetween. In a preferred embodiment, the thickness of the mask layer 145 is about 20 nm.

Referring still to FIG. 3, in a preferred embodiment, the lithographic films 150, 155 and 160 are an optical diffusion layer 150 (herein “ODL”), silicon anti-reflective coating 155 (herein “SiARC”), and photoresist 160 (herein “resist”). One skilled in the art will recognize that an ODL or SiARC may or may not be used depending upon underlying films, underlying topology and ground rules. Finally, note, in FIG. 3, an opening 161 in the resist layer 160 has already been patterned. In a preferred embodiment, the opening 161 in the resist layer 160 is aligned such that it is over the first sidewall 123 of the deep trench 120, but not over the second 124 sidewall.

Finally, with respect to FIG. 3 and all following figures, the bottom portion of the substrate 100, where the deep trench 120 ends, is no longer shown for simplicity.

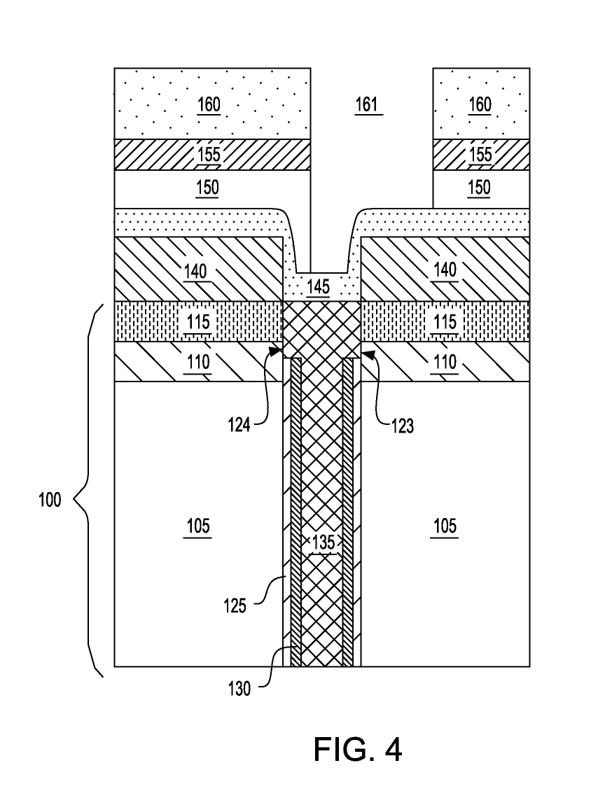

Referring to FIG. 4, the method entails a series of etching steps through the remaining lithographic films. One etch removes the SiARC 155 and stops on the ODL 150. Another etch removes the ODL 150 and stops on the mask layer 145. Suitable SiARC etches include dry etches using fluorine based chemistry and Suitable ODL etches include dry etches with similar chemistry. A “dry” etch can include sputter etching or reactive ion etching (herein “RIE”). In a preferred embodiment, the dry etch is a RIE. As can be seen in FIG. 4, the series of etches results in a portion of the mask layer 145 being exposed to opening 161 while a remaining portion of the mask layer 145 is under the lithographic films 150 and 155.

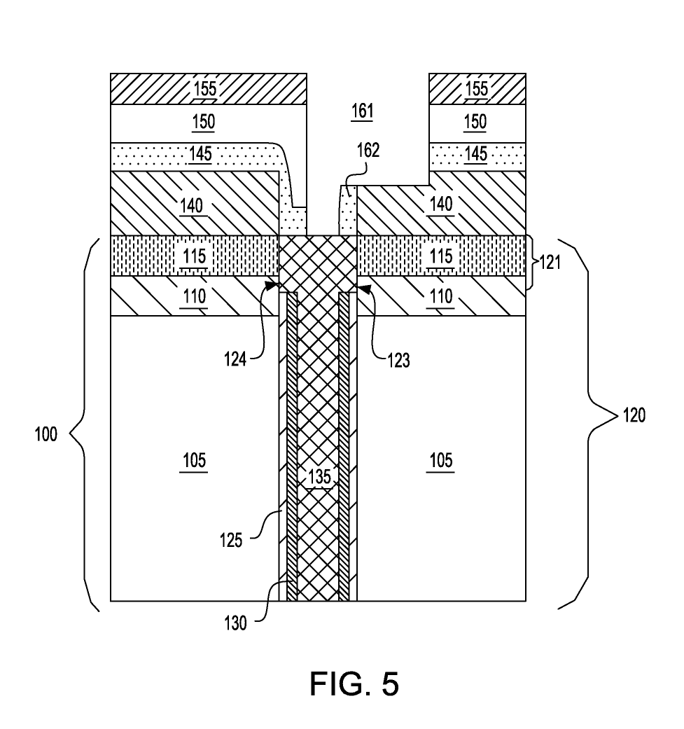

Referring to FIG. 5, the substrate is shown after patterning the mask layer 145 to form a first mask spacer 162. Here, the exposed portions of the mask layer 145 have been etched anisotropically, meaning the etch removed the mask layer 145 on horizontal surfaces faster than mask layer 145 on vertical surfaces. Or stated another way, the patterning etch is directional, in this case, etching down faster than etching side to side. As a result, the exposed portion mask layer 145 on top of the pad layer 140 is removed while the exposed portion of mask layer 145 on the vertical surface of the pad layer 140 remains. Thus, the following features are on the substrate after patterning the mask layer 145: a first mask spacer 162 made from the mask layer 145 material, an exposed portion of the pad layer 140, and an exposed portion of the fill material 135 in the upper portion 121 of the deep trench 120 (also referred to as “unmasked deep trench region”). Exposed, of course means, not covered by an overlying film.

Still referring to FIG. 5, at this point in the process, the first mask spacer 162 has a height approximately equal to the pad layer 140 and a width from about 5 nm to about 30 nm and ranges therebetween. Or stated another way, the width of the first mask should be on the order of or larger than the width of the liner film that will be protected. In FIG. 5 liner film can include 125, 130, or both. The width of the first mask spacer 162 can be controlled by one or both of (1) the initial thickness of the as formed mask layer 145, and (2) the amount of over etch during the patterning step. Suitable etch chemistries to etch the mask layer 145 to form the first mask spacer 162 are fluorine based dry etches.

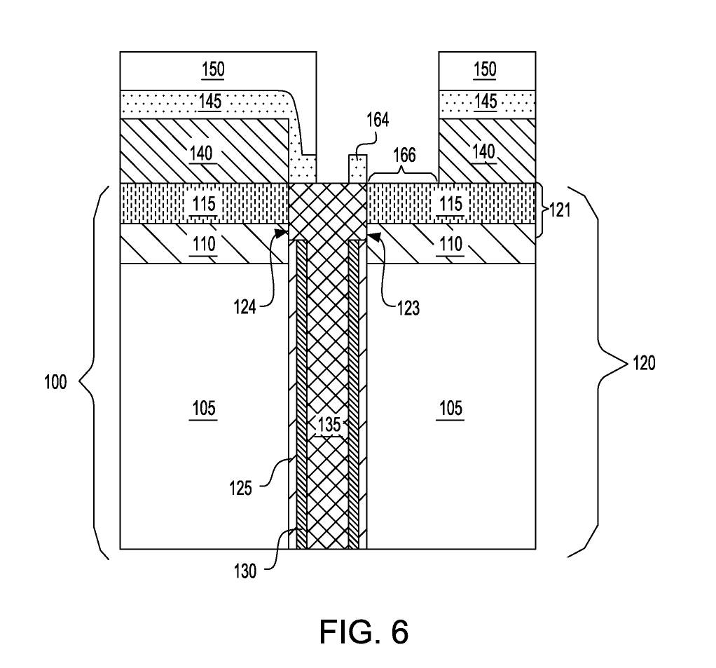

Referring to FIG. 6, the substrate is shown after etching the exposed portion of the pad layer 140 to form a free standing first mask 164. In a preferred embodiment, the etch is selective, meaning it etches the pad layer 140 at a greater rate than the mask layer 145 material. The selectivity can be from about 2:1 to about 40:1 and ranges therebetween. The selective etch is preferably anisotropic. By using a directional etch, the selectively etched first mask spacer 162 largely maintains its width; thus the resulting first mask 164 is as wide or wider than the liner film (125, 130 or both) to be protected. The height of the first mask spacer 162 is reduced during the etch; thus the resulting first mask 164 is shorter than the first mask spacer 162 from which it derived. The height of the first mask 164 after the selective etch can be about 20 nm. The selective etch should also be selective to the fill material 135. In such a way, the exposed fill material 135 is not appreciably etched during first mask 164 formation. In addition to forming the first mask 164, the selective etch also results in the exposed portion of the pad layer 140 being removed to expose a portion 166 of the SOI Layer 115. Thus, after selective etching, the substrate 100 has a first mask 164 vertically aligned over the liner film to be protected (125, 135 or both), an exposed portion of fill material 135 in the upper portion 121 of the deep trench 120, and an exposed portion 166 of the SOI layer 115. The SOI layer 115 having the exposed portion 166 is adjacent a first sidewall 123 of the deep trench. Similarly, the liner film to be protected (125, 135 or both) is adjacent the first sidewall 123 of the deep trench 120. Suitable selective etch chemistries include fluorine based dry etches.

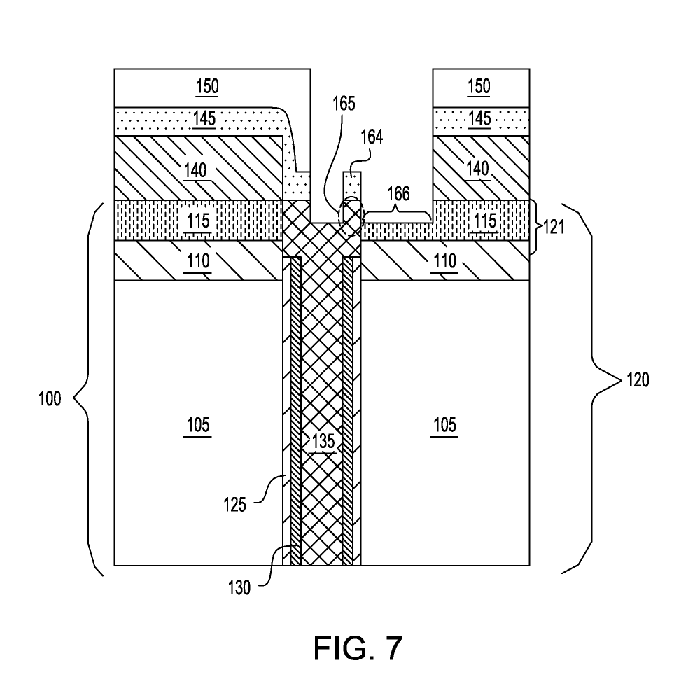

Referring to FIG. 7, the substrate is shown after a first, partial, silicon etch of the exposed portion 166 of the SOI layer 115 and of the exposed portion of the fill material 135 (also referred to as “unmasked deep trench region”) to form a tab 165 in the upper portion 121 of the deep trench 120. The first etch is partial meaning not the entire SOI layer 115 thickness is removed. The amount etch during the partial etch is not critical.

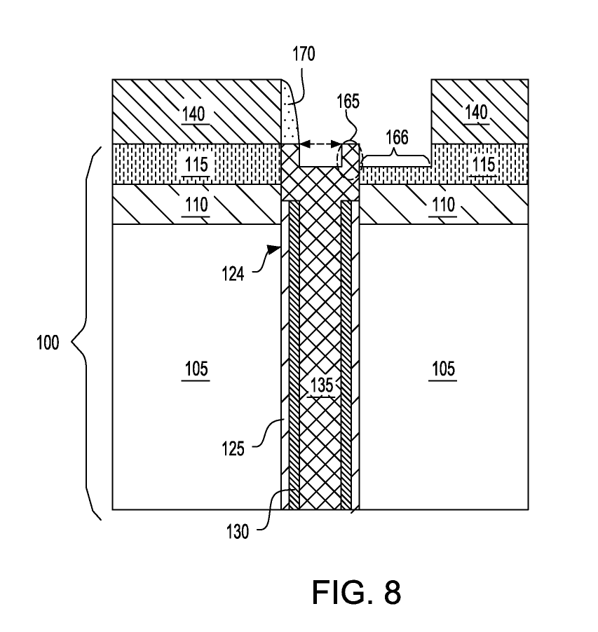

Referring to FIG. 8, after the first silicon etch, any remaining lithographic stack materials are removed (i.e. “stripped”). Because the liner films (125, 130 or both) are protected by the first mask 164 and tab 165, the strip of any remaining lithographic stack can be aggressive. The aggressive strip reduces defects and improves yield. Removing any remaining lithographic stack materials exposes a remaining portion of the mask layer 145 over the pad layer 140 that was previously covered by the stack (note, the remaining portion of the mask 145 over the pad layer 140 are not shown in FIG. 8).

Still referring to FIG. 8, mask layer 145 is etched via RIE. The etch, like the one used to form the first mask 164, is directional and may be the same etch as used in making the first mask 164. The etch removes the first mask 164 and anisotropically etches the remaining portion of the mask layer to form a second mask 170. The second mask 170 is vertically aligned over the liner films (125, 130 or both) adjacent the second sidewall 124 of the deep trench 120. At this point, the height of the tab 165 can be approximately the same level as the fill material 135 under the second mask 170 as denoted by the dotted line with arrows.

Instead of comparing the height of the top of the tab 165 to fill material 135 under the second mask 170, protection offered by the tab can also be viewed as the amount of fill material 135 over the liner film on the first sidewall 123. There can be from about 1 nm to about 90 nm, and ranges therebetween, of fill material 135 (which includes the tab 165) over the liner film on the first sidewall 123. In a preferred embodiment, there is 30 nm of fill material 135 (which includes the tab) above the liner film on the first sidewall 123.

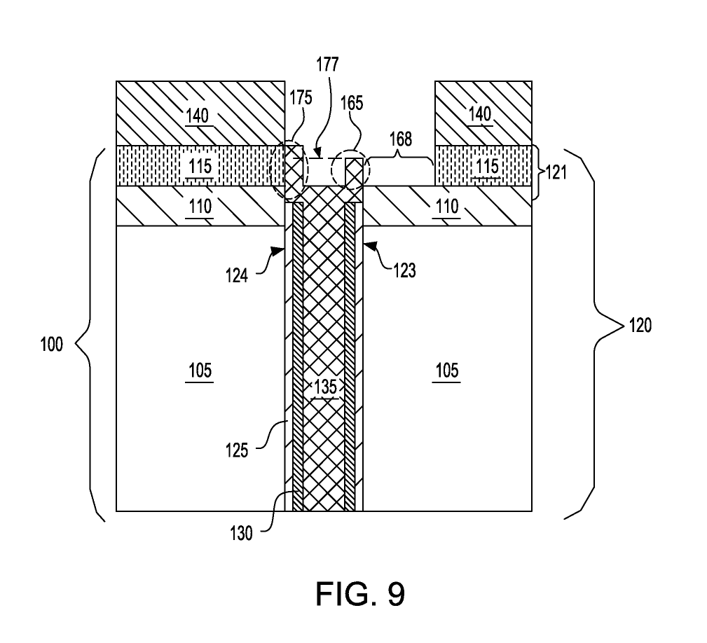

Referring to FIG. 9, a second silicon etch etches the exposed portions of the fill material 135 in the upper portion 121 of the deep trench 120. Note, now that the first mask 164 has been removed, the tab 165 is part of that exposed portion of the fill material in the upper portion of the deep trench which is etched. In addition, the second silicon etch removes any remaining exposed portion 166 of the SOI layer 115 to expose a portion of the Box 110 (see reference numeral 168 identifying exposed portion of insulator layer/Box). During the second silicon etch the tab 165 is etched while the area under the second mask is protected. Thus, after the second silicon etch and after removing the second mask 170, a structure as illustrated in FIG. 9 is achieved. Note, that etching the exposed fill material 135 while protecting a portion of fill with the second mask 170, created a strap 175 of fill material 135 which aligns vertically with the liner films (125, 130 or both) on the second sidewall 124 of the deep trench 120. The strap 175 provides a conduction path from the fill material 135 of the deep trench 120 to the SOI layer 115. Also note that prior to the second etch, the tab 165 and the material that becomes the strap 175 have tops which are at the same height (see, dotted double headed arrow of FIG. 8). However during the second silicon etch, the tab 165 is exposed while the future strap 175 material is protected by the second mask 170. Therefore, after the second silicon etch, the top of the strap 175 and the top of the tab 165 are at different levels as indicated by the dotted line 177 showing the height differences. Finally, with respect to the first and second silicon etches, they are both RIE and can be the same chemistry, namely chlorine, or bromine based.

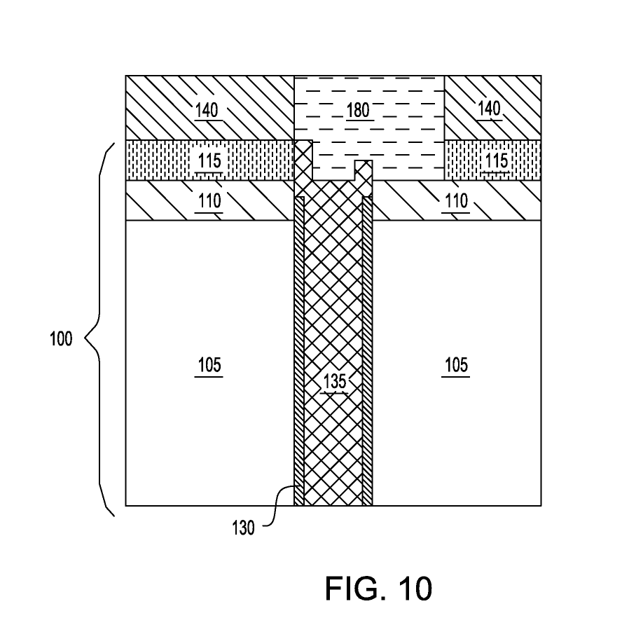

Referring to FIG. 10, an isolation film is deposited over the substrate and planarized. The isolation film 180 may be one or more dielectric films deposited from one or more of the following methods, including but not limited to, chemical vapor deposition (CVD), plasma enhanced chemical vapor deposition (PECVD), spin on, atomic layer deposition (ALD), high density plasma deposition (HDP). In a preferred embodiment, the isolation film is an oxygen containing film. In another preferred embodiment, the isolation film is a silicon oxide film (SiOₓ and its hydrogen, nitrogen and doped derivatives including SiOH, SiON, PSG, BPSG, for example). In a preferred embodiment, the isolation film is deposited by HDP. The isolation film can be a high-k material, meaning its dielectric constant is greater than 4.0, or can be a non-high-k material (i.e. dielectric constant equal to or less than 4.0).

Still referring to FIG. 10, after deposition, the isolation film 180 is planarized to be co-planar with the pad layer 140. The planarization step may be by etching or polishing. In a preferred embodiment the isolation film 180 is polished.

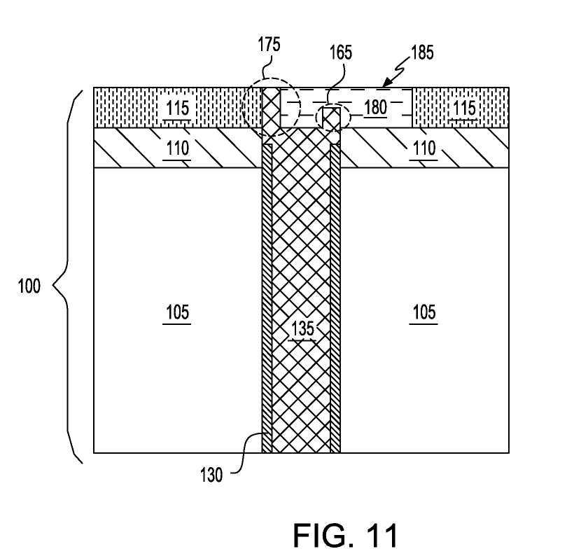

Referring to FIG. 11, the pad layer 140 is removed and the isolation layer 180 is planarized to be co-planar with the SOI layer 115 to form isolation region 185. The isolation region 185 can be a shallow trench isolation (STI) region. From this point on, formation steps to continue the device build are followed.

Still referring to FIG. 11, features of the isolation region 185 filled with isolation layer 180 are discussed. The isolation layer 180 is above the tab 165 and surrounds the tab. The isolation layer 180 is adjacent the strap 175. The isolation layer 180 of the isolation region is not in contact with the liner film (125, 130 or both) of the deep trench 120; instead, fill material 135 separates the isolation region 185 from the liner film.

An advantage of the disclosed method is that a previously formed deep trench module is protected from subsequent processing steps used to make later modules (for example, a shallow trench isolation module (“STI”)). The deep trench module includes the deep trench 120 with liner film (125, 130 or both) and fill material 135. In particular, this method protects the liner film (125, 130 or both) adjacent sidewall 123 which is vulnerable to exposure when etching to form the STI. The sidewalls 123 and 124 and their adjacent liner films are protected because the method provides an intervening tab 165 or strap 175, respectively, formed from the fill material 135 and aligned over the areas to be protected. Thus, as seen in FIG. 11, the isolation region 185 is separated from the liner (125,130 or both) of the first sidewall 123 by tab 165 which is made from fill material 135 (i.e. polysilicon). Similarly, strap 175 protects sidewall 124 and its liner film (125, 130 or both).

Another advantage of the disclosed method of protecting sidewalls of a formed deep trench module from subsequent processing steps is that one lithography step is used to form two masks (the first 164 and second 170 masks) which result in the protecting tab 165 and strap 175.

Furthermore, from the single lithography step, protecting tab 165 and strap 175 can have heights different from each other. The different heights afford different functions for the features. Therefore, from one lithography step, two features (tab 165 and strap 175) can be formed which can serve multiple functions. The tab 165 and strap 175 both serve a protection function during processing, but the strap 175 can also serve an electrical function to connect one area of the device (deep trench capacitor) to another (transistor).

Yet another advantage of the method is that the first 164 and second 170 masks are self-aligned by the pad opening 142. By self-aligning with the pad opening 142, the first 164 and second 170 masks will automatically be vertically aligned with the deep trench sidewalls 123 and 124, respectively. As a result, the tab 165 and strap 175 will be self-aligned to protect the liner films adjacent the respective sidewalls 123 and 124.

While the present invention has been described with reference to what are presently considered to be the preferred embodiments, it is to be understood that the invention is not limited to the disclosed embodiments. On the contrary, the invention is intended to cover various modifications and equivalent arrangements included within the spirit and scope of the appended claims. The scope of the following claims is to be accorded the broadcast interpretation so as to encompass all such modifications and equivalent structures and functions.

What is claimed is:

1. A method of protecting a deep trench liner film from damage during processing, the method comprising:
providing a semiconductor on insulator (SOI) substrate having an SOI layer, an insulator layer, a deep trench and a pad layer; wherein the SOI layer is above the insulator layer;
wherein the deep trench has a first sidewall;
wherein the deep trench has a liner film adjacent a lower portion of the first sidewall; and
wherein the deep trench has a silicon containing material;
wherein the pad layer is above the SOI layer and has a pad opening above the deep trench;
patterning a first mask aligned over the liner film; and
etching, with a first silicon etch, the SOI layer and the silicon containing material to form a tab of silicon containing material aligned over the liner film adjacent the first sidewall.

2. The method of claim 1, further comprising:
depositing an isolation film; and
planarizing the isolation film to form an isolation region over the tab.

3. The method of claim 1, wherein the deep trench has a second sidewall with the liner film adjacent the lower portion of the second sidewall.

4. The method of claim 3, further comprising, prior to patterning the first mask, forming a mask layer above the substrate.

5. The method of claim 4, further comprising:
etching the mask layer to form a second mask aligned above the liner film adjacent the second sidewall.

6. The method of claim 5, further comprising:
removing the first mask.

7. The method of claim 5, further comprising:
etching, with a second silicon etch, the silicon containing material to form a silicon containing strap layer adjacent the second sidewall.

8. The method of claim 7, further comprising:
depositing an isolation film; and
planarizing the isolation film to form an isolation region, wherein the isolation regions is over the tab, and adjacent the silicon containing strap.

9. The method of claim 7, wherein etching with the second silicon etch exposes a portion of the insulator layer.

10. The method of claim 9, wherein said depositing and planarizing the isolation film forms an isolation region contiguous with the exposed insulator layer.

11. The method of claim 7, further comprising:
removing the second mask.

12. The method of claim 1, wherein said patterning the first mask further comprises:
depositing a mask layer,
depositing a lithographic stack including a resist layer;
patterning the resist layer;
etching the lithographic stack stopping on the mask layer to expose a portion of the mask layer;
removing the resist layer; and
etching a horizontal surface of the exposed mask layer to form a first mask spacer.

13. The method of claim 12, further comprising, after said etching a horizontal surface of the exposed mask layer:
etching the pad layer to form an exposed portion of the SOI layer and the first mask.

14. The method of claim 13, wherein said etching the pad layer comprises selectively etching the pad layer to the mask layer.

15. The method comprising:
depositing a mask layer over a pad opening wherein the pad opening is aligned with a deep trench in a substrate, wherein the deep trench has a first sidewall and a second sidewall;
forming an opening in a lithographic stack wherein the opening is aligned over the first sidewall of the deep trench;
etching the mask layer to form a first mask aligned over the first sidewall;
etching a silicon containing layer in the deep trench to from a tab of silicon containing material aligned over the first sidewall;
removing the lithographic stack;
etching the mask layer to form a second mask aligned over the second sidewall; and
etching the silicon containing material to form a strap.

16. The method of claim 15, further comprising:
depositing an isolation film; and
planarizing the isolation film to form an isolation region, wherein the isolation regions is over the tab, and adjacent the silicon containing strap.

17. A structure formed in a substrate, the structure comprising:
a deep trench having a first sidewall, a liner adjacent the first sidewall and a silicon containing fill material wherein a portion of the silicon containing fill material is over the liner adjacent the first sidewall; and
an isolation film above the portion of the silicon containing fill material over the liner adjacent the first sidewall.

18. The structure of claim 17, further comprising:
an SOI layer; and
a strap portion of the silicon containing fill material adjacent the SOI layer.

19. The structure of claim 18, wherein the SOI layer, the isolation film and the strap are coplanar.

20. The structure of claim 18, wherein a top of the strap is higher than a top of the tab.
